(19) United States
(12) Patent Application Publication
(10) Pub. No.: US 2007/0122560 A1
(43) Pub. Date: May 31, 2007

(54) Solid-free-form fabrication process including in-process component deformation

(75) Inventor: Robbie J. Adams, Phoenix, AZ (US)

Correspondence Address: HONEYWELL INTERNATIONAL INC., 101 COLUMBIA ROAD, P O BOX 2245, MORRISTOWN, NJ, 07962-2245, US

(73) Assignee: Honeywell International, Inc.

(21) Appl. No.: 11/292,041

(22) Filed: Nov. 30, 2005

(51) Int. Cl. C23C 14/00; B05D 3/02; B05D 1/36; B29C 71/04

(52) U.S. Cl. 427/523; 427/402; 427/372.2; 427/532

(57) ABSTRACT

A solid free form fabrication method is performed for manufacturing a component from successive layers of metal feedstock material, with each of the successive layers representing a cross-sectional component slice. First, a first of the successive layers is formed by directing the feedstock material to a predetermined region, the layer comprising at least one crystal grain. Then, the at least one crystal grain is deformed to create dislocations therein. A second layer is formed on the first layer, and the first and second layers are heated to form new crystal grains that are differently sized than the at least one crystal grain.

### TECHNICAL FIELD

The present invention relates to the fabrication of parts and devices, and more particularly relates to solid free-form fabrication processes that create parts and devices by selectively applying feedstock material to a substrate or an in-process workpiece.

### BACKGROUND

Solid free-form fabrication (SFF) is a designation for a group of processes that produce three dimensional shapes from additive formation steps. SFF does not implement any part-specific tooling. Instead, a three dimensional component is often produced from a graphical representation devised using computer-aided modeling (CAM). This computer representation may be, for example, a layer-by-layer slicing of the component shape into consecutive two dimensional layers, which can then be fed to control equipment to fabricate the part. Alternatively, the manufacturing process may be user controlled instead of computer controlled. Generally speaking, a component may be manufactured using SFF by successively building feedstock layers representing successive cross-sectional component slices. Although there are numerous SFF systems that use different components and feedstock materials to build a component, SFF systems can be broadly described as having an automated platform/positioner for receiving and supporting the feedstock layers during the manufacturing process, a feedstock supplying apparatus that directs the feedstock material to a predetermined region to build the feedstock layers, and an energy source directed toward the predetermined region. The energy from the energy source modifies the feedstock in a layer-by-layer fashion in the predetermined region to thereby manufacture the component as the successive layers are built onto each other.

One recent implementation of SFF is generally referred to as ion fusion formation (IFF). With IFF, a torch such as a plasma, gas tungsten arc, plasma arc welding, or other torch with a variable orifice is incorporated in conjunction with a stock feeding mechanism to direct molten feedstock to a targeted surface such as a base substrate or an in-process structure of previously-deposited feedstock. A component is built using IFF by applying small amounts of molten material only where needed in a plurality of deposition steps, resulting in net-shape or near-net-shape parts without the use of machining, molds, or mandrels. The deposition steps are typically performed in a layer-by-layer fashion wherein slices are taken through a three dimensional electronic model by a computer program. A positioner then directs the molten feedstock across each layer at a prescribed thickness.

There are also several other SFF process that may be used to manufacture a component. Direct metal deposition, layer additive manufacturing processes, and selective laser sintering are just a few SFF processes. U.S. Pat. No. 6,680,456, discloses a selective laser sintering process that involves selectively depositing a material such as a laser-melted powdered material onto a substrate to form complex, net-shape objects. In operation, a powdered material feeder provides a uniform and continuous flow of a measured amount of powdered material to a delivery system. The delivery system directs the powdered material toward a deposition stage in a converging conical pattern, the apex of which intersects the focal plane produced by a laser in close proximity to the deposition stage. Consequently, a substantial portion of the powdered material melts and is deposited on the deposition stage surface. By causing the deposition stage to move relative to the melt zone, layers of molten powdered material are deposited. Initially, a layer is deposited directly on the deposition stage. Thereafter, subsequent layers are deposited on previous layers until the desired three-dimensional object is formed as a net-shape or near net-shape object. Other suitable SFF techniques include stereolithography processes in which a UV laser is used to selectively cure a liquid plastic resin.

When building a metal component using many SFFF process, the mechanical properties of the metal product may be limited by the metal's grain size. Relatively large grains is sometimes an inherent trait of materials formed using SFFF. For example, IFF in essence is a weld deposition process, and welds tend to have somewhat large columnar grains. Metals having small equiaxed grains typically have higher strength than metals having relatively large grains.

Hence, there is a need for SFFF processes such as IFF that include a technique for improving a workpiece material's strength after heated feedstock is deposited onto a targeted surface to form the workpiece. There is a further need for a technique that optimizes grain size and thereby improves the workpiece material's mechanical properties.

### BRIEF SUMMARY

The present invention provides a solid free form fabrication method for manufacturing a component from successive layers of metal feedstock material, with each of the successive layers representing a cross-sectional component slice. First, a first of the successive layers is formed by directing the feedstock material to a predetermined region, the layer comprising at least one crystal grain. Then, the at least one crystal grain is deformed to create dislocations therein. A second layer is formed on the first layer, and the first and second layers are heated to form new crystal grains that are differently sized than the at least one crystal grain.

The present invention also provides another solid free form fabrication method. First, successive layers are formed by directing the feedstock material to predetermined regions, the layers together comprising at least one crystal grain. Then, the at least one crystal grain is deformed to creating dislocations therein. Finally, the layers are heated to form new crystal grains that are smaller than the at least one crystal grain.

Other independent features and advantages of the preferred apparatus and method will become apparent from the following detailed description, taken in conjunction with the accompanying drawings which illustrate, by way of example, the principles of the invention.

### BRIEF DESCRIPTION OF THE DRAWINGS

FIG. 1 is a perspective view of an IFF system according to an embodiment of the invention;

FIG. 2 is a cross-sectional view of a torch from an IFF system, the torch functioning in cooperation with a wire feed mechanism, which is depicted in a perspective view;

FIG. 3A is a cross-sectional view of a first layer formed by SFFF and undergoing crystal deformation using a plunger that contacts the first layer;

FIG. 3B is a cross-sectional view of the first layer from FIG. 3A after undergoing crystal deformation and having reduced grain sizes as a result;

FIG. 3C is a cross-sectional view of the first layer from FIG. 3B, along with a newly formed second layer formed by SFFF and undergoing crystal deformation using a plunger;

FIG. 3D is a cross-sectional view of the first and second layers from FIG. 3C after having the second layer undergo crystal deformation;

FIG. 3E is a cross-sectional view of the first and second layers from FIG. 3D, along with a newly formed third layer formed by SFFF;

FIG. 4 is a cross-sectional view of a first layer formed by SFFF and undergoing crystal deformation from pulses of energy produced using a laser beam;

FIG. 5 is a cross-sectional view of a first layer formed by SFFF and undergoing crystal deformation from a column of hot gas flowing from a heat source; and

FIG. 6 is a cross-sectional view of three layers formed by SFFF, with energy focused toward a point within the structure to cause internal crystal deformation.

### DETAILED DESCRIPTION OF A PREFERRED EMBODIMENT

The following detailed description of the invention is merely exemplary in nature and is not intended to limit the invention or the application and uses of the invention. Furthermore, there is no intention to be bound by any theory presented in the preceding background of the invention or the following detailed description of the invention.

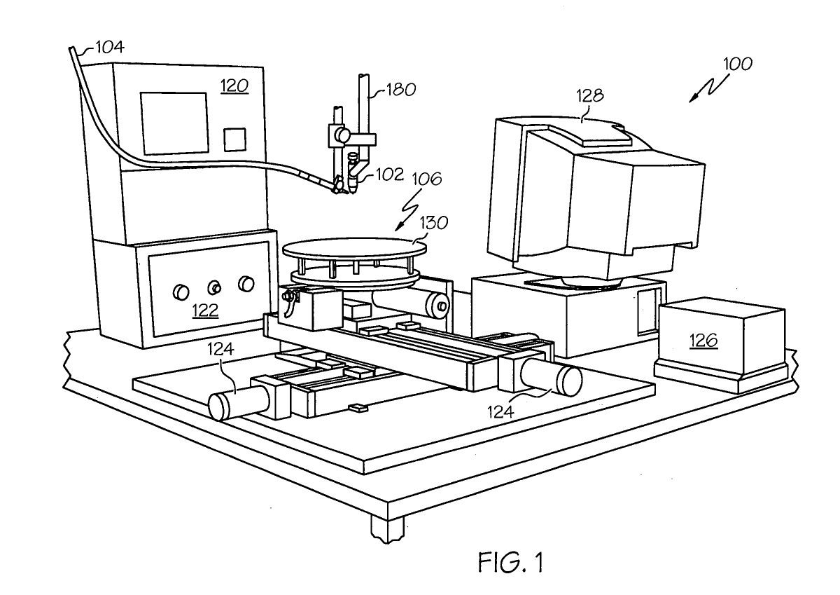

FIG. 1 is a perspective view of an IFF system 100, which includes a torch 102 that functions in cooperation with a wire feed mechanism 104 and a positioning system 106 to build up a workpiece in a continuous or layer-by-layer manner. The positioning system 106 continuously positions and repositions the workpiece in a manner whereby feedstock material may be added to it through the wire feed mechanism 104 at predetermined deposition points. Further, the positioning system 106 may also be configured to coordinate movement and control of the torch 102 and the wire feed mechanism 104 together with the workpiece to fabricate three-dimensional articles in a predictable, highly selectable, and useful manner. Control of the positioning system 106 may be achieved by computer-implemented control software or the like. The coordinated torch 102, wire feed mechanism 104, and positioning system 106 provide a highly flexible, manually adaptable, and spontaneously constructible automated system through which components may be fabricated to net or near-net shape.

Additional elements depicted in FIG. 1 include a gas controller 120 that controls gas and/or fluid flow to the torch 102, which is preferably a plasma welding torch. A plasma or arc power source 122 supplies the necessary power to the torch 102. Positioners and/or positioning motors 124 are supplied with positioning signals from an electric drive 126 that is coupled to a computer 128 or other controlling device.

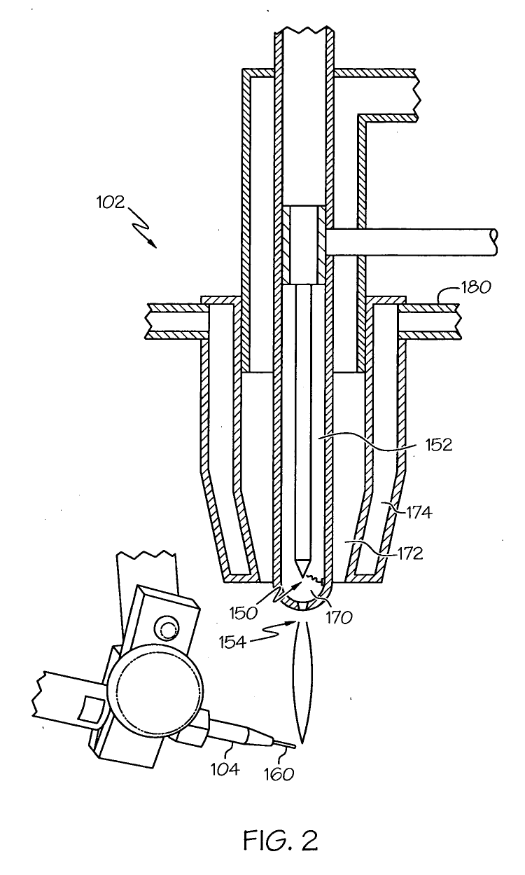

A cross-sectional view of the torch 120 is depicted in detail in FIG. 2 in cooperation with a wire feed mechanism 104. An arc electrode 150 is positioned near a nozzle 154 and inside a gas flow channel 152, and operates to ionize a gas and create a hot argon plasma in region 170 before the gas exits the nozzle 154. Upon being energized, the argon gas rapidly accelerates from the nozzle 154 toward the workpiece. The wire feed mechanism 104 introduces feedstock 160 between the nozzle 154 and the workpiece. In an exemplary embodiment, the workpiece is included in an electrical circuit including the ionized gas in order to accelerate and attract the ions from the nozzle 154. The workpiece may be charged by applying a voltage that is opposite of the charge generally present in the ionized plasma gas. The ionized gas is then electrically attracted to the workpiece. Use of such electrical charge in the workpiece may also serve to control the direction and distribution of the ionized plasma gas. The degree of attraction between the ions and the workpiece may be controlled by increasing or decreasing the charge present on the workpiece.

A noble gas such as argon is preferably ionized using the arc electrode 150, although alternative inert gases, ions, molecules, or atoms may be used in conjunction with the torch 102 instead of argon. These alternative mediators of the plasma energy may include positive and/or negative ions, or electrons alone or together with ions. Further, reactive elements may be combined with an inert gas such as argon to optimize performance of the torch 102. The plasma generating process so energizes the argon gas that the gas temperature is raised to between 5,000 and 30,000 K. Consequently, only a small volume of energized argon gas is required to melt feedstock 160 from the wire feed mechanism 104. Nozzles of varying apertures or other orifices may be used to provide specific geometry and plasma collimation for the fabrication of different components. Direct beam nozzle orifices may contrast with nozzles having a fan shape or other shapes.

The ionized argon plasma, and all other ionized noble gases, has strong affinity for electrons and will obtain them from the surrounding atmosphere unless the atmosphere consists of gases having equal or higher electron affinity. One advantage of the exemplary IFF system depicted in the drawings does not require a pressurization chamber or other chamber in which the ambient gas is controlled. However, to prevent the ionized argon plasma from obtaining electrons and/or ions from the surrounding atmosphere, i.e. from nitrogen and oxygen typically present in ambient environments, the ionized argon plasma is sheathed or protected by a curtain of helium, another noble gas, or other inert gases flowing from the nozzle from a coaxial channel 172. Helium and other noble gases hold their electrons with a high degree of affinity, and are less susceptible than oxygen or nitrogen to having its electrons taken by the ionized argon plasma.

Collisions between the energetic argon atom and the nozzle 154 may substantially heat and damage the nozzle if left unchecked. To cool the nozzle 154, water or another cooling fluid is circulated in a cooling chamber 174 that surrounds the nozzle 154. A gas and water flow line 180 leads into the cooling chamber 174.

Any material susceptible to melting by an argon ion or other plasma beam may be supplied using a powder feed mechanism or the wire feed mechanism 104 as feedstock 160. Such materials may include steel alloys, aluminum alloys, titanium alloys, nickel alloys, although numerous other materials may be used as feedstock depending on the desired material characteristics such as fatigue initiation, crack propagation, post-welding toughness and strength, and corrosion resistance at both welding temperatures and those temperatures at which the component will be used. Specific operating parameters including plasma temperatures, build materials, melt pool parameters, nozzle angles and tip configurations, inert shielding gases, dopants, and nozzle coolants may be tailored to fit an IFF process. U.S. Pat. No. 6,680,456 discloses an IFF system and various operating parameters, and is hereby incorporated herein by reference.

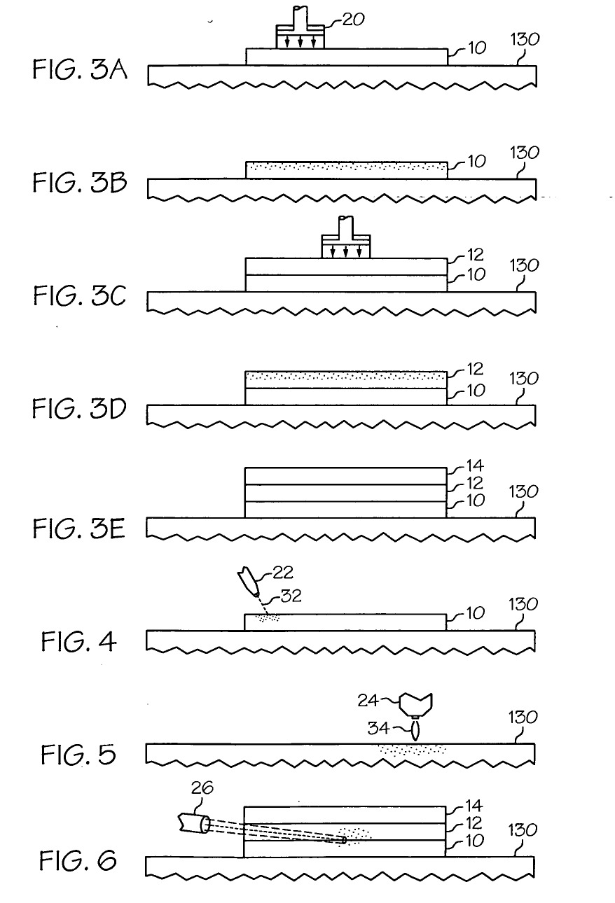

As previously discussed, when building a component using IFF or any SFFF process, the mechanical properties of the metal product may be limited if the metal's grain size is too large. Metals having relatively small equiaxed grains typically have higher strength than metals having larger grains. Relatively large grains may be an inherent trait of materials formed using SFFF depending on deposition parameters. For example, metal components produced using IFF or other direct metal deposition processes may have somewhat large columnar grains. FIGS. 3A to 3E depict an exemplary SFFF method that includes in-situ mechanical deformation and recrystallization of deposited metal material between deposition steps. The deformation and recrystallization steps reduce the deposited material average grain size and thereby increase the strength. As will be subsequently discussed, non-mechanical methods may also be used to induce crystal deformation. Factors such as the timing and rate of deposition, or auxiliary heating rates and during deposition, will affect the grain size and phase distribution if secondary phases exist in the metal. These factors have an impact on the metal's mechanical properties, and the type and extent of the deformation process that is to be performed on the deposited metal layers.

As depicted in FIG. 3A, a first layer 10 is deposited onto a platform 130 during a SFFF process. With the first layer 10 still on the platform 130, crystal deformation of the layer material is mechanically induced. Although there are numerous ways to mechanically induce crystal deformation, an exemplary method includes actuation of a plunger 20 to force a load against the first layer 10. The load applied by the plunger 20 is sufficient to deform the crystal in at least an upper region of the first layer 10 although the load may be sufficient to induce crystal deformation all the way across the first layer 10. The plunger 20 may be actuated using pneumatic force created by an assembly such as a piston subjected to pressurized gas. Another possible mechanism to actuate the plunger 20 may be a solenoid that includes a metal shaft that forces the plunger 20 when actuated by a magnetic force induced by a surrounding coil. Other mechanisms such as a cam, etc. may be used to actuate the plunger 20 or other mechanical devices and thereby exert a load on the first layer 10.

According to a preferred embodiment, crystal deformation is performed at or below the metal's recrystallization temperature in order for the effects of crystal deformation to be maintained. The load may also be applied while the first layer 10 is higher than the metal's recrystallization temperature, and especially at temperatures significantly above the recrystallization temperature, and large crystal grains may thereby be formed in or restored into the first layer 10. In contrast, when performing crystal deformation at or below the metal's recrystallization temperature the small grains produced by the deformation process are preserved.

FIG. 3B depicts the first layer 10 after undergoing crystal deformation. At least some regions in the crystal structure are dislocated as indicated by the broken lines in the first layer 10. The dislocations will subsequently serve as nucleation sites for growth of new crystal grains, which are smaller than the crystal grains in the first layer 10 before being subjected to the mechanical load.

In FIGS. 3C and 3D, the process depicted in FIGS. 3A and B is repeated by first depositing a second layer 12 onto the first layer 10, and then subjecting the second layer 12 to a load applied by the plunger 20 sufficient to deform the crystal in at least an upper region of the second layer 12. Again, the load may be sufficient to induce crystal deformation all the way across the first layer 10. Heat from the second layer 12 during deposition causes new crystals to grow from the dislocations in the first layer 10. Growth of the new crystals removes the dislocations and restores organization to the metal's crystal structure, although now with relatively small grains. After the plunger causes crystal deformation in the second layer 12, a third layer 14 is deposited onto the second layer as depicted in FIG. 3E. The heat from the third layer 14 during deposition causes new crystals to grow from the dislocations in the second layer 12, again removing the dislocations and restoring organization to the metal's crystal structure. The process is repeated for each layer deposition until the SFFF process is completed and a component is built from the successively formed layers.

In a preferred method, the plunger or other device that causes crystal deformation is actuated automatically after each layer deposition, or after a predetermined number of layer depositions. The SFFF apparatus may be equipped with a mechanism that follows a layer deposition device and exerts a deformation stress between deposition passes once the previously-deposited layer is cooled to or below the recrystallization temperature for the metal in the layer.

Turning now to FIG. 4, a laser shock peening device 22 is incorporated instead of a plunger as another exemplary mechanism for inducing crystal deformation in the first layer 10. The laser shock peening device 22 emits a laser 32 that is pulsed with a sufficient force to induce crystal deformation. The laser 32 creates dislocations in the first layer 10, and the dislocations serve as nucleation sites for new crystals when the dislocations are removed and structure is restored to the first layer 10 when another layer is deposited. Again, the procedure is repeated until the SFFF process is completed and a component is built from the successively formed layers.

FIG. 5 depicts another exemplary mechanism for inducing crystal deformation in the first layer 10. Instead of a mechanical or laser peening mechanism, a flowing hot gas is pulsed with sufficient velocity to induce crystal deformation. In one exemplary embodiment, the hot gas is pulsed using a torch 24 such as a plasma welding torch 24. The torch 24 may be an IFF torch such as the torch 102 previously discussed regarding an exemplary IFF procedure. The hot gas from the torch 24 creates dislocations in the first layer 10, and the dislocations create nucleation sites for new crystal when the dislocations are removed and structure is restored to the first layer 10, the restored structure resulting from heat when another layer is deposited. As with the previously-discussed embodiments, the procedure is repeated until a component is built from the SFFF process.

Although all of the previously-described methods include a crystal deformation process that is performed at a feedstock layer surface, other exemplary methods include inducement of crystal deformation from a structure's interior. FIG. 6 is a cross-sectional view of three layers 10, 12, and 14 formed by SFFF, with energy focused toward a point within the layers to cause internal crystal deformation. An energy beam is emitted from a device 26 and focused onto an interior region inside of a structure consisting of at least the layers 10, 12, and 14, and in the depicted embodiment between previously-formed layers 10 and 12. Exemplary energy sources may include eddy currents, microwaves, and x-rays, although these are just a few other exemplary energy sources that could be used to heat a structure interior area. The heated region will attempt to expand when heated, and constraint from the relatively cold surrounding material exerts a counterforce that deforms the heated region and creates crystal dislocations. More particularly, deformation is facilitated by reduced yield strength caused by the elevated temperature of the heated interior region. Again, the dislocations create nucleation sites for new crystal when the dislocations are removed and structure is restored by heating the overall structure either by performing additional SFFF steps or by heating the structure as a whole. Although these energy sources have been discussed as means for heating the component interior, they may also be directed to the component exterior and thereby heat the component from its exterior surfaces. The heat will subsequently be transferred to the component interior, and crystal dislocations will be produced from the force of interior expansion.

Thus, the SFFF methods of the present invention include various mechanisms for inducing crystal deformation after heated feedstock is deposited to form a workpiece. The crystal deformation methods may be performed between successive feedstock depositions using some mechanisms, but may also be performed by creating stress between layers after two or more feedstock layers have been deposited. Exemplary methods incorporate the crystal deformation procedures while the component is positioned on a building platform, so all the manufacturing and deformation processes may be performed in-situ, without the need to move the workpiece from one station to another between each successive feedstock deposition. The SFFF methods, including the crystal deformation steps, enable the control and optimization of component grain size and thereby improve the component strength.

While the invention has been described with reference to a preferred embodiment, it will be understood by those skilled in the art that various changes may be made and equivalents may be substituted for elements thereof without departing from the scope of the invention. In addition, many modifications may be made to adapt to a particular situation or material to the teachings of the invention without departing from the essential scope thereof. Therefore, it is intended that the invention not be limited to the particular embodiment disclosed as the best mode contemplated for carrying out this invention, but that the invention will include all embodiments falling within the scope of the appended claims.

We claim:

1. A solid free form fabrication method for manufacturing a component from successive layers of metal feedstock material, with each of the successive layers representing a cross-sectional component slice, the method comprising:
forming a first of the successive layers by directing the feedstock material to a predetermined region, the layer comprising at least one crystal grain;
deforming the at least one crystal grain and thereby create dislocations therein;
forming a second layer on the first layer; and
heating the first and second layers to form new crystal grains that are differently sized than the at least one crystal grain.

2. The method of claim 1, wherein the solid free form fabrication method is an ion fusion formation method.

3. The method of claim 1, wherein heating the first and second layers is inherently performed by forming the second layer.

4. The method of claim 1, wherein deforming the at least one crystal grain comprises applying a mechanical load to the first layer.

5. The method of claim 4, wherein the mechanical load is applied using a plunger.

6. The method of claim 1, wherein deforming the at least one crystal grain comprises laser shock peening the first layer.

7. The method of claim 1, wherein deforming the at least one crystal grain comprises flowing pulses of hot gas onto the first layer.

8. A solid free form fabrication method for manufacturing a component from successive layers of metal feedstock material, with each of the successive layers representing a cross-sectional component slice, the method comprising:
forming successive layers by directing the feedstock material to predetermined regions, the layers together comprising at least one crystal grain;
deforming the at least one crystal grain and thereby creating dislocations therein; and
heating the layers to form new crystal grains that are smaller than the at least one crystal grain.

9. The method according to claim 8, wherein deforming the at least one crystal grain comprises heating a selected internal region within the layers.

10. The method according to claim 9, wherein heating an internal region within the layers comprises penetrating the layers with energy created from an energy source selected from the group consisting of an energy beam, eddy currents, microwaves, and x-rays.

11. The method according to claim 8, wherein deforming the at least one crystal grain comprises directing heat onto an exterior region of the combined layers.

12. The method according to claim 11, wherein heating an exterior region of the combined layers is performed using energy created from an energy source selected from the group consisting of an energy beam, eddy currents, microwaves, and x-rays.

13. The method of claim 8, wherein the solid free form fabrication method is an ion fusion formation method.

14. An ion fusion formation method for manufacturing a component from successive layers of feedstock material, with each of the successive layers representing a cross-sectional component slice, the method comprising:
forming a first of the successive layers by melting the feedstock material using a hot plasma gas, and directing the melted feedstock material to a first predetermined region, the layer comprising at least one crystal grain;
creating dislocations in the at least one crystal grain; and
forming a second layer on the first layer by melting additional feedstock material using a hot plasma gas, and directing the melted additional feedstock material to a second predetermined region on the first layer, such that heat from the additional feedstock material causes removal of the dislocations and formation of new crystal grains that are smaller than the at least one crystal grain.

15. The method of claim 14, wherein deforming the at least one crystal grain comprises applying a mechanical load to the first layer.

16. The method of claim 15, wherein the mechanical load is applied using a plunger.

17. The method of claim 14, wherein deforming the at least one crystal grain comprises laser shock peening the first layer.

18. The method of claim 14, wherein deforming the at least one crystal grain comprises flowing pulses of hot gas onto the first layer.
